(19) United States
(12) Patent Application Publication
(10) Pub. No.: US 2015/0372099 A1
(43) Pub. Date: Dec. 24, 2015

(54) CONTACT SILICIDE FORMATION USING A SPIKE ANNEALING PROCESS

(71) Applicant: TAIWAN SEMICONDUCTOR MANUFACTURING COMPANY, LTD., Hsin-Chu (TW)

(72) Inventors: Sheng-Wen Chen, Tainan City (TW); Yu-Ting Lin, Tainan City (TW); Jemmy Tsai, Toufen Township (TW); Wei-Ming You, Taipei City (TW); Ting-Chun Wang, Tainan City (TW)

(21) Appl. No.: 14/308,976

(22) Filed: Jun. 19, 2014

(51) Int. Cl. H01L 29/40; H01L 21/265; H01L 21/768; H01L 29/417; H01L 29/49

(52) U.S. Cl. CPC H01L 29/401; H01L 29/41725; H01L 29/4933; H01L 21/76805; H01L 21/76883; H01L 21/265

(57) ABSTRACT

A substrate is provided. The substrate has a source/drain region formed therein and a dielectric layer formed thereover. A contact hole is etched in the dielectric layer to expose a portion of the source/drain region. A metal material is formed on the source/drain region exposed by the opening. A first annealing process is performed to facilitate a reaction between the metal material and the portion of the source/drain region disposed therebelow, thereby forming a metal silicide in the substrate. The first annealing process is a spike annealing process. A remaining portion of the metal material is removed after the performing of the first annealing process. Thereafter, a second annealing process is performed. Thereafter, a contact is formed in the contact hole, the contact being formed on the metal silicide.

### PRIORITY CLAIMS AND CROSS-REFERENCE

The present application is related to U.S. patent application Ser. No. 14/209,374, entitled “Contact Silicide Having a Non-Angular Profile,” filed on Mar. 13, 2014, attorney docket number TSMC 2013-1690/24061.2760, the entire disclosure of which is hereby incorporated by reference.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component that can be created using a fabrication process) has decreased.

As the semiconductor industry progresses into nanometer technology process nodes in pursuit of higher device density, higher performance, and lower costs, challenges from both fabrication and design have resulted in the development of multilayer (or three dimensional) integrated devices. For example, as device sizes continue to shrink, conventional methods of forming contact holes (or contacts) have led to problems such as non-uniform silicide grain size, excessive contact resistance, leakage issues, etc. As a result, semiconductor device performance may be degraded and defect count may increase. Therefore, while existing methods of fabricating semiconductor devices have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 and 7-9 are simplified diagrammatic cross-sectional side views of a semiconductor device at various stages of fabrication in accordance with some embodiments.

FIGS. 6A and 6B are annealing profiles associated with an example conventional annealing process and an embodiment of a spike annealing process of the present disclosure, respectively.

FIGS. 10A and 10B are cross-sectional profiles of an example metal silicide formed by a conventional process and an embodiment of a metal silicide formed by the processes of the present disclosure, respectively.

FIG. 11 is a flowchart illustrating a method of fabricating a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

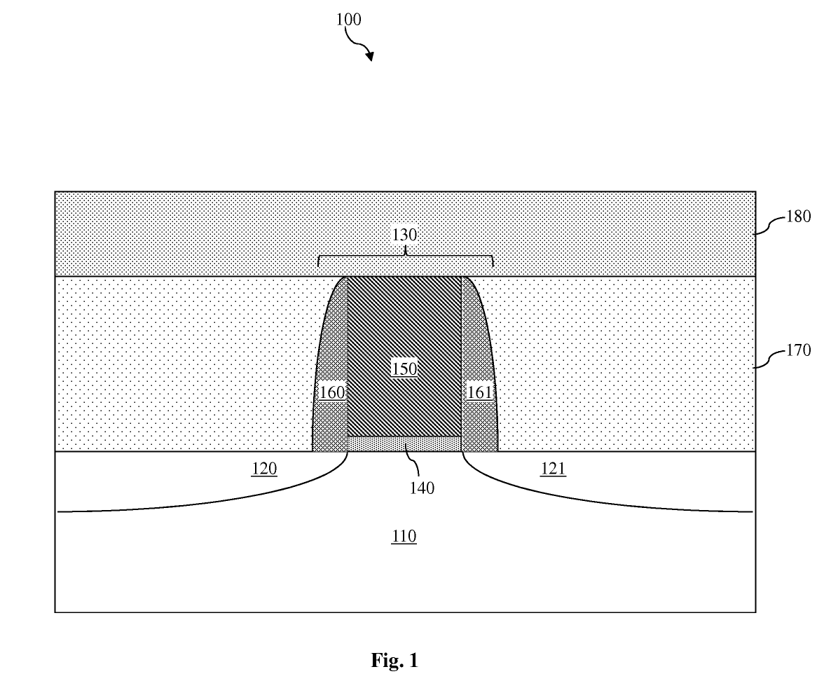

FIGS. 1-5 and 7-9 are diagrammatic fragmentary cross-sectional side views of a semiconductor device 100 at various stages of fabrication. The semiconductor device 100 may include an integrated circuit (IC) chip, system on chip (SoC), or portion thereof. The semiconductor device 100 may also include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistors. It is understood that FIGS. 1-5 and 7-9 have been simplified for a better understanding of the inventive concepts of the present disclosure, and various elements of the semiconductor device 100 may not be specifically illustrated for reasons of simplicity.

Referring to FIG. 1, the semiconductor device 100 includes a substrate 110. In the illustrated embodiment, the substrate 110 is a silicon substrate, though it is understood that other types of substrates may also be used in alternative embodiments. For example, the substrate 110 may also be a silicon germanium substrate, silicon carbide substrate, etc. The substrate 110 may also be slightly doped, for example by an n-type dopant or a p-type dopant.

The substrate 110 may include various doped regions, such as source/drain regions 120-121 of a transistor device. The source/drain regions 120-121 may be n-type regions in a p-type substrate 110, or may be p-type regions in an n-type substrate 110. The source/drain regions 120-121 may also each include a lightly-doped portion and a heavily doped portion, which are not specifically illustrated for reasons of simplicity.

A gate structure 130 is formed over the substrate 110. The gate structure 130 includes a gate dielectric 140, a gate electrode 150 formed over the gate dielectric 140, and gate spacers 160 disposed on sidewalls of the gate dielectric 140 and the gate electrode 150. It is understood that the gate dielectric 140 and the gate electrode 150 are formed before the source/drain regions 120-121 are formed in the substrate. In some embodiments, the gate dielectric 140 and the gate electrode 150 may be used to define the lightly-doped portions of the source/drain regions 120-121, and the spacers 160-161 may be used to define the heavily-doped portions of the source/drain regions 120-121.

In some embodiments, the gate dielectric 140 contains silicon oxide, and the gate electrode 150 contains polysilicon. In other embodiments, a gate-replacement process may also be used to form a high-k metal gate. In those embodiments where the gate structure 130 is a high-k metal gate, the gate dielectric 140 contains a high-k dielectric material, and the gate electrode 150 contains a metal material. A high-k dielectric material is a material having a dielectric constant that is greater than a dielectric constant of SiO₂, which is approximately 4. For example, the high-k dielectric material may include hafnium oxide (HfO₂), which has a dielectric constant that is in a range from approximately 18 to approximately 40. Alternatively, the high-k material may include one of ZrO₂, Y₂O₃, La₂O₅, Gd₂O₅, TiO₂, Ta₂O₅, HfErO, HfLaO, HfYO, HfGdO, HfAlO, HfZrO, HfTiO, HfTaO, SrTiO, or combinations thereof.

The metal material of the gate electrode 150 may include a work function metal component and a fill metal component. The work function metal component may be N-type and includes Ti, Al, Ta, ZrSi₂, or TaN, or it may be P-type and includes Mo, Ru, Ir, Pt, PtSi, MoN, or WNx. The work function metal component has a range of work functions values associated therein. The work function metal component tunes a work function of the transistor device (e.g., formed by the gate structure 130 and the source/drain regions 120-121) so that a desired threshold Vₜ voltage is achieved.

The fill metal component of the metal gate electrode serves as the main conductive portion of the gate electrode. The fill metal component may include tungsten, aluminum, copper, or combinations thereof. For the sake of simplicity, the work function metals and the fill metal portions are not separately drawn.

In a gate-replacement process, a dummy gate electrode (typically made of polysilicon) may be formed on the high-k dielectric. After the formation of the source/drain regions 120-121, the dummy gate electrode may be removed and replaced by the metal gate electrode discussed above. This is referred to as a gate-last process flow. In some embodiments, the gate-replacement process may also employ a high-k last process flow, in which a dummy oxide dielectric is formed in place of the high-k dielectric. A dummy polysilicon gate electrode is formed on the dummy oxide gate dielectric. After the formation of the source/drain regions 120-121, the dummy oxide gate dielectric is removed along with the dummy polysilicon gate electrode. The high-k gate dielectric and the metal gate electrode may then be formed to replace the removed dummy gate dielectric and dummy gate electrode.

As is illustrated in FIG. 1, an inter-layer (or inter-level) dielectric (ILD) layer 170 is formed over the substrate 110. The ILD layer 170 may be formed by chemical vapor deposition (CVD), high density plasma CVD, spin-on, sputtering, or other suitable methods. In some embodiments, the ILD layer 170 includes silicon oxide. In other embodiments, the ILD layer 170 may include silicon oxy-nitride, silicon nitride, or a low-k material. The ILD layer 170 surrounds the gate structure 130. A layer 180 is formed over the ILD layer 170. The layer 180 may be a sealing layer to protect the layers and components therebelow. The layer 180 may include a plurality of sub-layers, which are not specifically illustrated for reasons of simplicity.

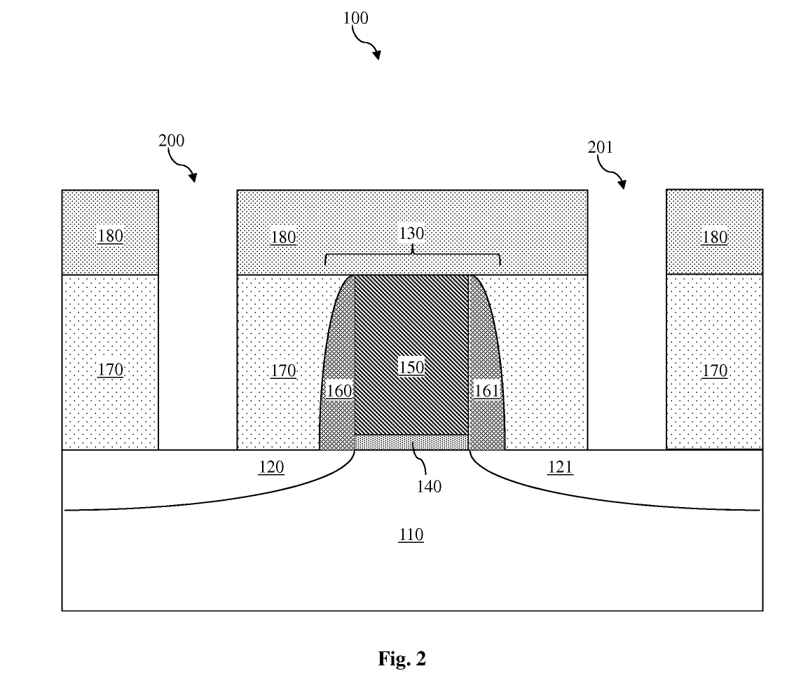

Referring now to FIG. 2, openings 200-201 are formed in the layer 180 and the ILD layer 170. The openings 200-201 may be formed by one or more etching processes known in the art, or by another suitable technique. The openings 200-201 are reserved for the formation of conductive contacts in a later process. These conductive contacts establish electrical connections with source/drain regions 120-121. As such, the openings 200-201 are formed to expose portions of the source/drain regions 120-121, so that a conductive material that is deposited into the openings 200-201 may be in electrical contact with the source/drain regions 120-121.

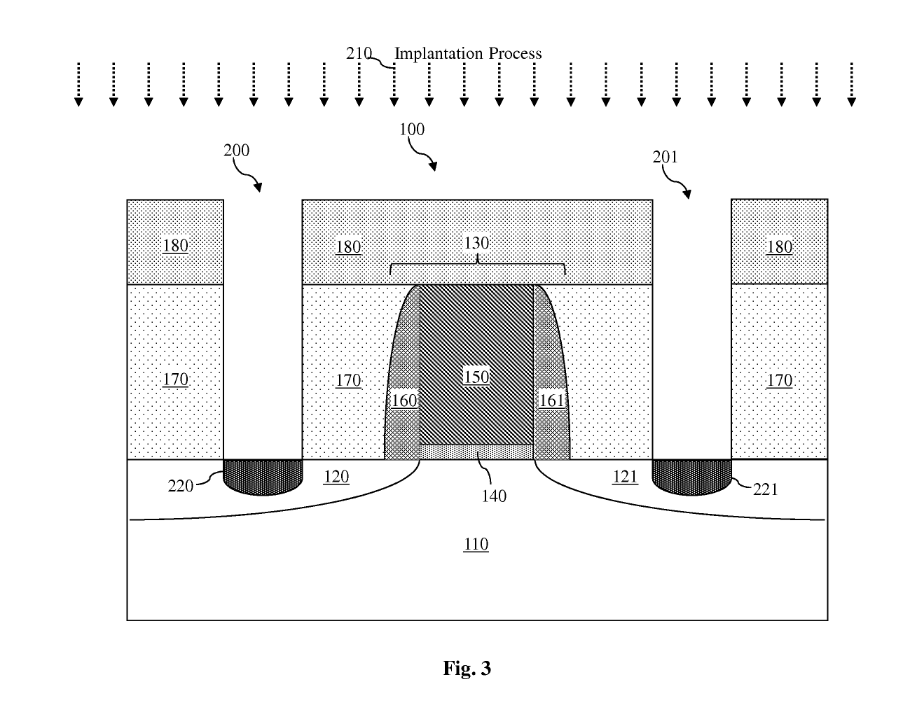

Referring now to FIG. 3, an implantation process 210 is performed. As a part of the implantation process 210, ions bombard the substrate 110 through the openings 200-201, so as to destroy the crystal structure of the silicon material in the portions of the substrate 110 disposed below the openings 200-201. In other words, these portions of the substrate 110 become amorphized after the performance of the implantation process 210, meaning that the silicon material in these portions becomes amorphous silicon.

As illustrated in FIG. 3, amorphous silicon regions 220-221 are formed by the performance of the ion implantation process 210. The amorphous silicon regions 220-221 are respectively formed in portions of the source/drain regions 120-121 exposed by the openings 200-201. In some embodiments, the amorphous silicon regions 220-221 are formed to partially have a curved or non-angular cross-sectional profile. For example, a bottom surface (and partially the side surfaces) of the amorphous silicon regions 220-221 may be somewhat rounded. In some embodiments, the amorphous silicon regions may have a partial cross-sectional profile that approximately resembles an ellipse. According to various aspects of the present disclosure, such amorphous silicon regions 220-221 will lead to better silicide formation, as discussed in more detail below.

In some embodiments, the implantation process 210 may be a cold implantation (or cryo-implantation) process. In other words, the temperature is kept low as the implantation process 210 is performed. For example, the temperature of the implantation process 210 may be in a range from about −60 degrees Celsius to about −100 degrees Celsius. One reason for the low temperature range is to prevent self-annealing from occurring. In more detail, the process of ions being implanted generates heat. For typical implantation processes that are performed at room temperature or higher, the heat generated by the implantation may provide enough energy boost for the amorphized silicon in the regions 220-221 to repair its crystal structure, which is referred to as recrystallization. This process may also be referred to as a “self-annealing” process.

However, according to various aspects of the present disclosure, one of the goals of the implantation process 210 is to create amorphous silicon. It would be undesirable if the newly-created amorphous silicon regions 220-221 to subsequently transform back into a crystal silicon structure through the aforementioned self-annealing process. Thus, in order to prevent the self-annealing from occurring, the temperature of the implantation process 210 is kept low. The low temperature deprives the amorphous silicon in the regions 220-221 of the energy boost needed to recrystallize. Stated differently, when the annealing temperature is kept low, the heat generated by the implantation process alone is not sufficient to cause the amorphous silicon in the regions 220-221 to recrystallize. Hence, the amorphous silicon structure would be kept intact.

In some embodiments, the ions used in the implantation process 210 are silicon ions. In other embodiments, the ions may be germanium ions, xenon ions, or carbon ions._In some embodiments, the ion implantation process 210 has an implantation energy that is in a range from about 3 keV to about 15 keV, and may be performed for a process duration for about 5 seconds to about 100 seconds.

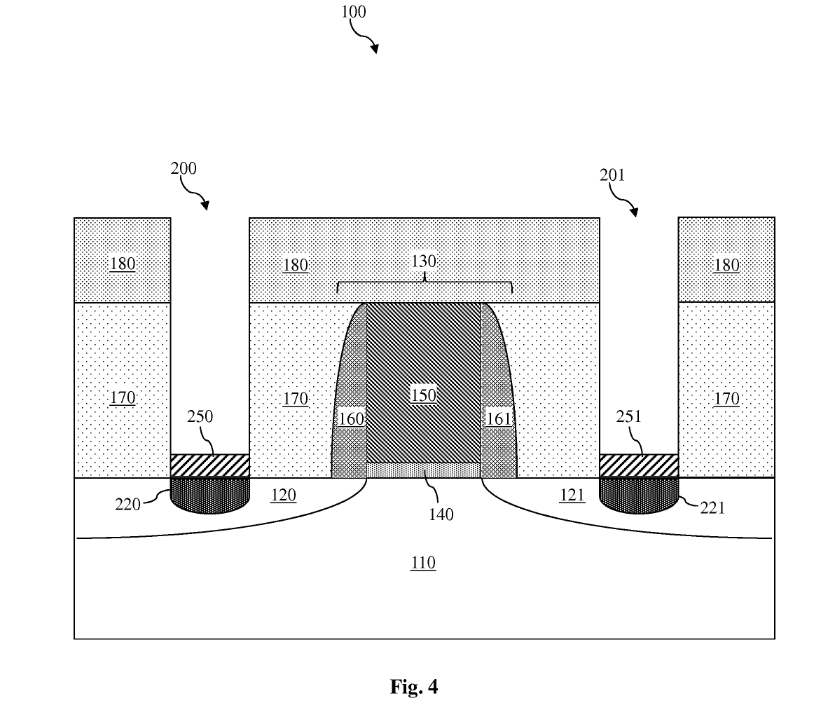

Referring now to FIG. 4, metal materials 250-251 are formed on the amorphous silicon regions 220-221 through the openings 200-201. In some embodiments, the metal materials 250-251 contain nickel. In various embodiments, the metal materials 250-251 may be formed on the surfaces of the amorphous silicon regions 220-221 via one or more deposition processes known in the art, for example CVD, physical vapor deposition (PVD), atomic layer deposition (ALD), or combinations thereof.

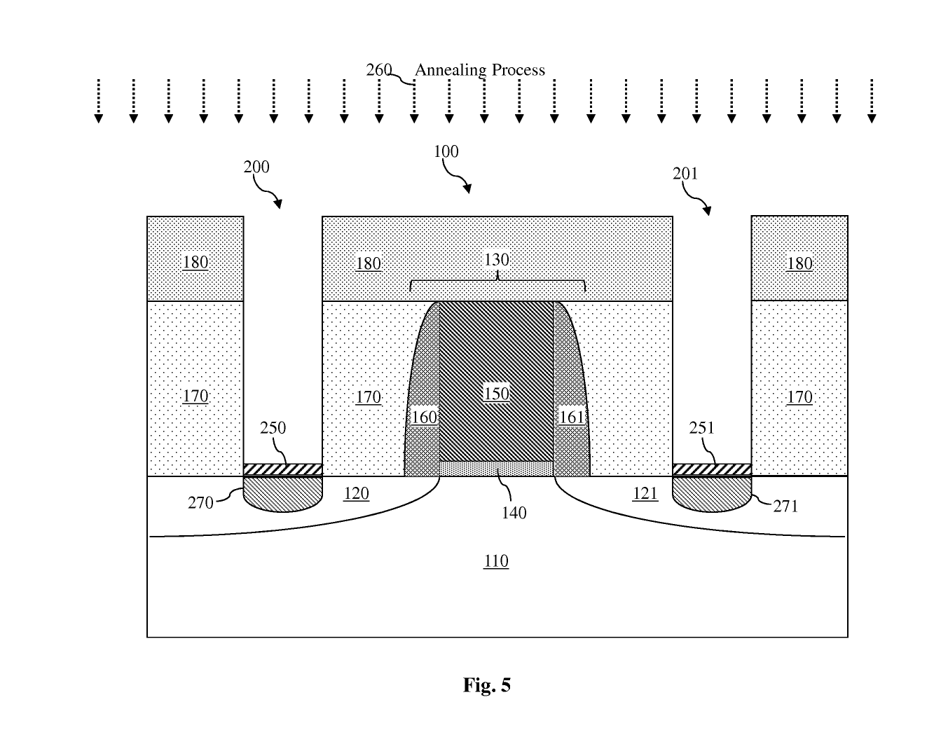

Referring now to FIG. 5, an annealing process 260 is performed to facilitate silicidation. In more detail, the annealing process 260 is performed in a manner such that the metal materials 250-251 will react with the amorphous silicon regions 220-221 below. This reaction leads to the formation of metal silicides 270-271 in place of the amorphous silicon regions 220-221. Alternatively stated, the amorphous silicon in the regions 220-221 is transformed into metal silicide via the reaction with the metal materials 250-251, which is facilitated by the annealing process 260. In embodiments where the metal materials contain nickel, the metal silicides 270-271 are nickel silicides (NiSi).

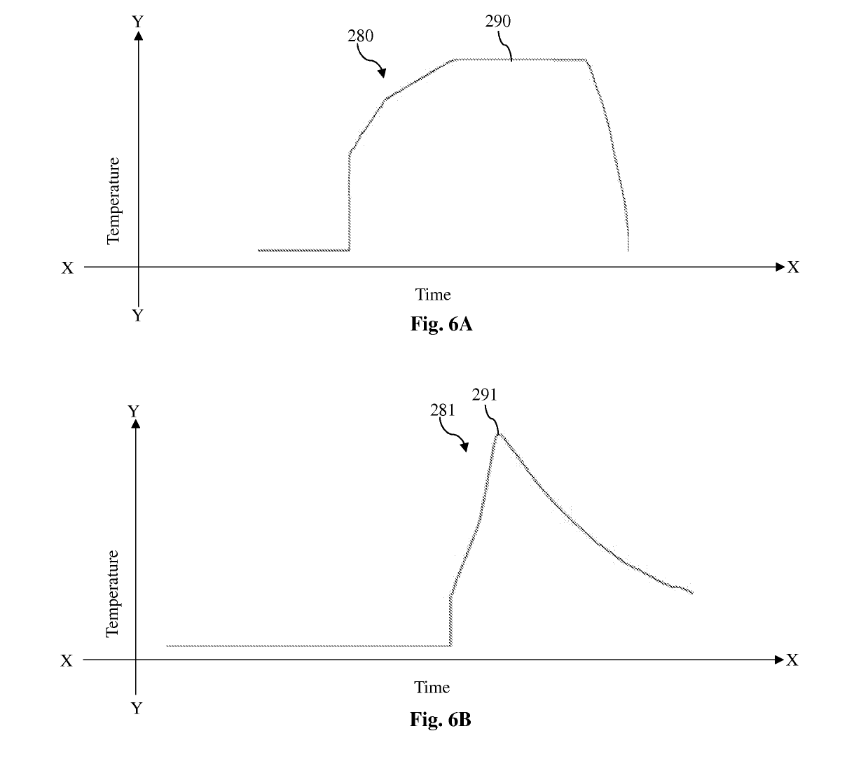

According to the various aspects of the present disclosure, the annealing process 260 has a unique profile compared to conventional annealing processes. In particular, the annealing process 260 is a spike annealing process (or includes a spike profile). This aspect of the annealing process 260 is explained in more detail with reference to FIGS. 6A and 6B.

In more detail, FIG. 6A illustrates an annealing profile of an example conventional annealing process, and FIG. 6B illustrates an annealing profile of an embodiment of the annealing process 260 shown in FIG. 5. In both FIGS. 6A and 6B, the annealing profile includes an X-axis that represents time, as well as a Y-axis that represents temperature. A plot 280 in FIG. 6A represents how the temperature of the conventional annealing process varies over time, and a plot 281 in FIG. 6B represents how the temperature of the embodiment of the annealing process 260 (FIG. 5) varies over time.

As illustrated in FIG. 6A, the plot 280 has a relatively slow ramp-up period. That is, temperature increases relatively slowly over time. For example, it may take from about 10 seconds to about 80 seconds for temperature to be ramped up to a range between about 200 degrees Celsius to about 300 degrees Celsius Once the temperature reaches a peak level 290, it stays there for a relatively long period of time. The temperature drops off after the annealing process is over.

In comparison, the plot 281 in FIG. 6B has a fast ramp up period. In the embodiment shown, the temperature has a drastic or rapid ascension (i.e., spike-like profile). For example, the temperature may reach a peak temperature 291 in just 10-60 seconds. In some embodiments, the peak temperature 291 is in a range from about 200 degrees Celsius to about 300 degrees Celsius. Once the peak temperature 291 is reached, it is maintained for a short duration. For example, in some embodiments, the peak temperature 291 is maintained for a time duration shorter than about 5 seconds, for example in a range from about 0.5 seconds to about 5 seconds. Afterwards, the temperature is ramped down, but more slowly than in conventional annealing processes.

One reason for the spike-like profile associated with the annealing process 260 is that it promotes uniform grain growth for the silicide. The inventors have discovered that, the long annealing time for conventional annealing processes (e.g., long duration at which the peak temperature 290 is maintained in FIG. 6A) tends to cause large size deviations in the metal silicide grains formed as a result of the annealing. This may be a result of different silicide grain particles being agglomerated over time, and the long annealing process time thus facilitates the agglomeration of the grain particles. The large deviations in grain size may degrade the performance of the metal silicide, as it may lead to current leakage or reliability issues.

In comparison, the spike-like profile for the annealing process 260 has a much shorter annealing duration, which reduces the agglomeration of silicide grain particles. Therefore, the metal silicides 270-271 (FIG. 5) formed as a result of the annealing process 260 will have more uniform grain sizes, thereby improving device performance and reducing potential defects or failures. For example, by performing the various processes of the present disclosure, the metal silicide grain size deviation may be controlled to be within (i.e., less or equal to) 5 nm. The relatively uniform silicide grain size of the present disclosure helps prevent leakage and may increase a stress voltage tolerance for a contact to be formed on the silicide.

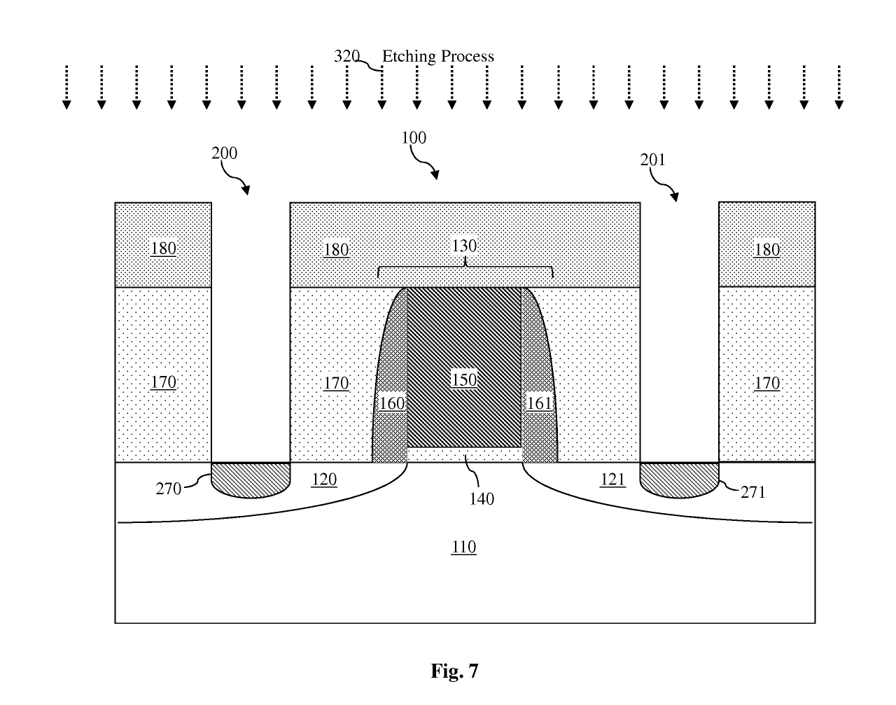

Referring now to FIG. 7, after the annealing process 260 has been performed, an etching process 320 is performed to remove portions of the metal material 250-251 that has not reacted with the amorphous silicon therebelow to form the metal silicides 270-271. In some embodiments, the etching process 320 is a selective etching process, and it etches away the metal materials 250-251 but not the metal silicides 270-271.

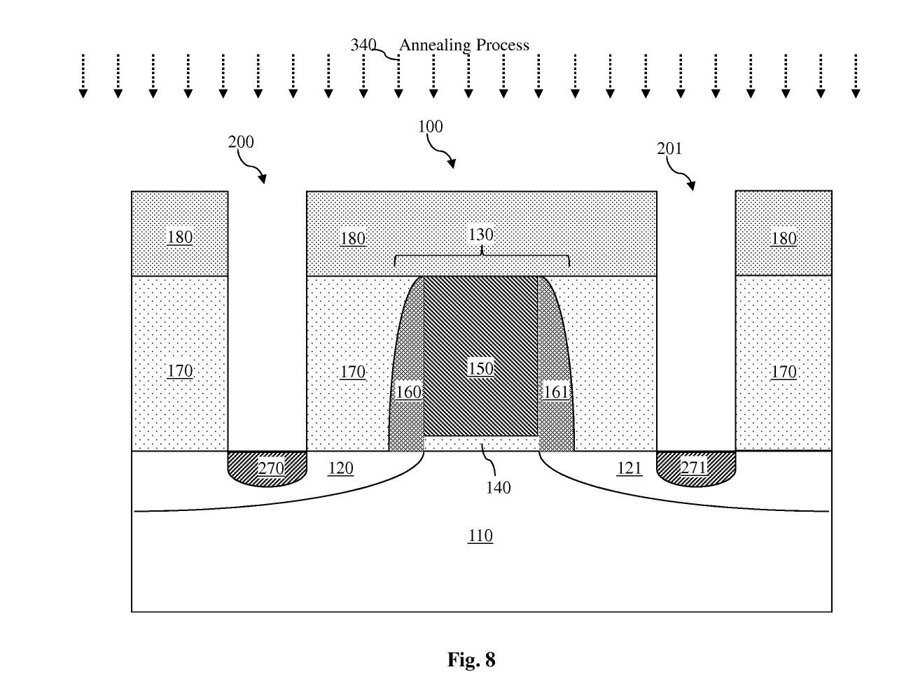

Referring now to FIG. 8, another annealing process 340 is performed to finalize the formation of the metal silicides 270-271. Unlike the annealing process 260, the annealing process 340 may or may not have a spike-like profile. In some embodiments, the annealing process 340 includes a rapid thermal annealing process or a laser annealing process. The annealing process 340 may cause whatever amorphous silicon that is remaining in the substrate 110 to recrystallize.

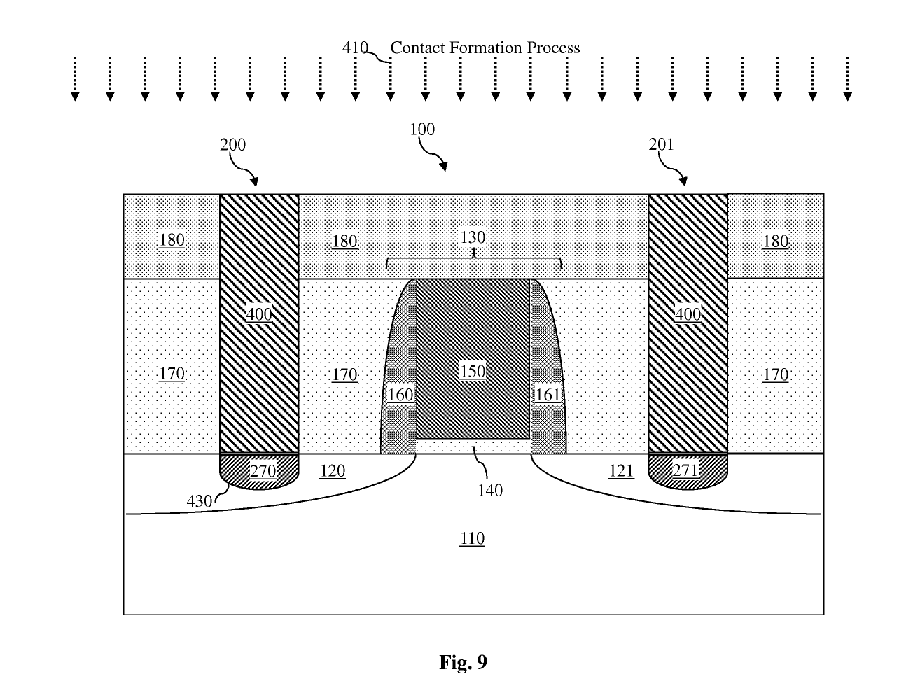

Referring now to FIG. 9, conductive contacts 400 and 401 are formed over the metal silicides 270-271 in the openings 200-201, respectively. The conductive contacts 400-401 may be formed by a contact formation process 410. In some embodiments, the contact formation process 410 may include a deposition process (e.g., CVD, PVD, ALD, etc.) to deposit a metal material such as tungsten, copper, or aluminum in the openings, followed by a polishing process to planarize the surface of the deposited metal so that it is substantially co-planar with the layer 180. In some embodiments, a barrier layer may also be formed prior to the deposition of the metal, so as to prevent diffusion from the conductive contact into the layer 170.

The metal silicides 270-271 serve as electrical interfaces between the conductive contacts 400-401 and the source/drain regions 120-121, respectively. Alternatively, the metal silicides 270-271 may be considered parts of the conductive contacts 400-401 themselves. In any case, since the electrical connection between the conductive contacts 400-401 and the source/drain regions are established through the metal silicides 270-271, it is desirable for the metal silicides 270-271 to have low resistance. Unfortunately, conventional methods of forming silicides usually lead to high resistance for the silicides.

According to the various aspects of the present disclosure, the metal silicides 270-271 have low resistance and high conductivity, which is at least in part attributed to the size and/or shape of the metal silicides. For example, due to the reaction with the amorphous silicon regions 220-221 (FIG. 4) in their formation, the metal silicides 270-271 mostly assume a shape or profile of the amorphous silicon regions 220-221. As discussed above, the amorphous silicon regions 220-221 may be formed to have partially rounded or curved (e.g., ellipse-like) cross-sectional profiles. As such, the metal silicides 270-271 may also at least in part assume such curved or rounded profiles. For example, a surface 430 of the metal silicide 270 may have a rounded or curved cross-sectional profile, which may resemble a portion of an ellipse.

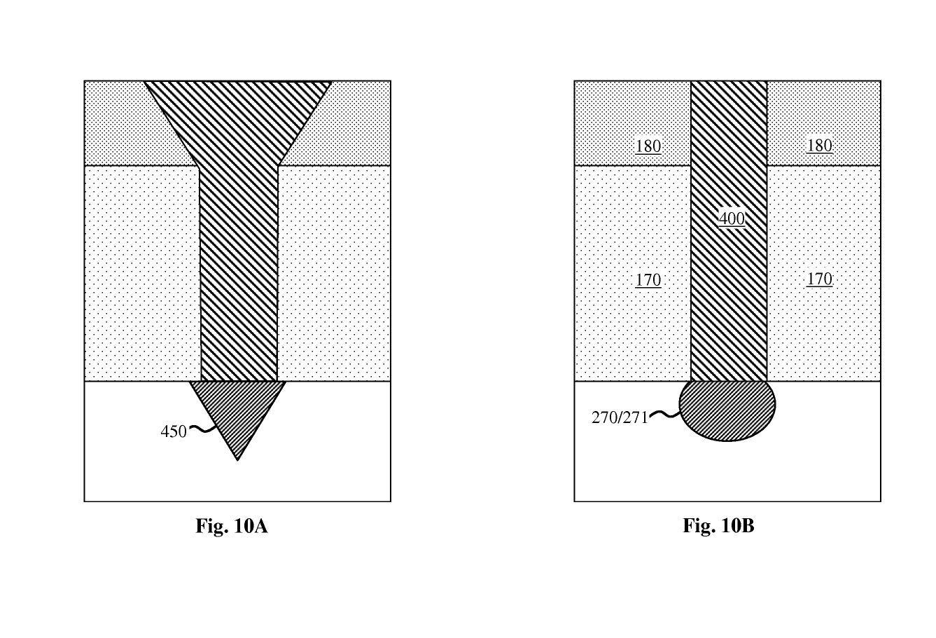

The non-angular profile of the metal silicides 270-271 is one of the visual characteristics of the semiconductor device 100 formed by the methods of the present disclosure, as conventional metal silicides may have a triangle-like shape, particularly in more advanced technology nodes such as a 20-nm technology node. For example, referring now to FIG. 10A, a cross-sectional profile picture of an example metal silicide 450 formed by a conventional process at a 20-nm technology node is shown. The metal silicide 450 has a triangular shape, which encloses a relatively small volume and therefore is associated with a greater resistance.

In comparison, FIG. 10B illustrates a cross-sectional profile picture of an embodiment of the metal silicide 270/271 formed using 20-nm technology node processes that incorporate the processes of the present disclosure. The metal silicide 270/271 has an approximately rounded or curved profile that may resemble an ellipse in this case. Among other things, such ellipse-like profile allows the metal silicide 270/271 to enclose a greater volume than the metal silicide 450. In other words, the metal silicide 270/271 formed by the methods of the present disclosure has a substantially greater volume (for example multiple times greater) than the metal silicide 450 formed by conventional processes. The greater volume leads to a lower resistance and higher conductivity. Thus, the metal silicides 270/271 formed by the processes of the present disclosure discussed above have improved performance (e.g., in terms of a contact resistance Rc) over conventional silicides.

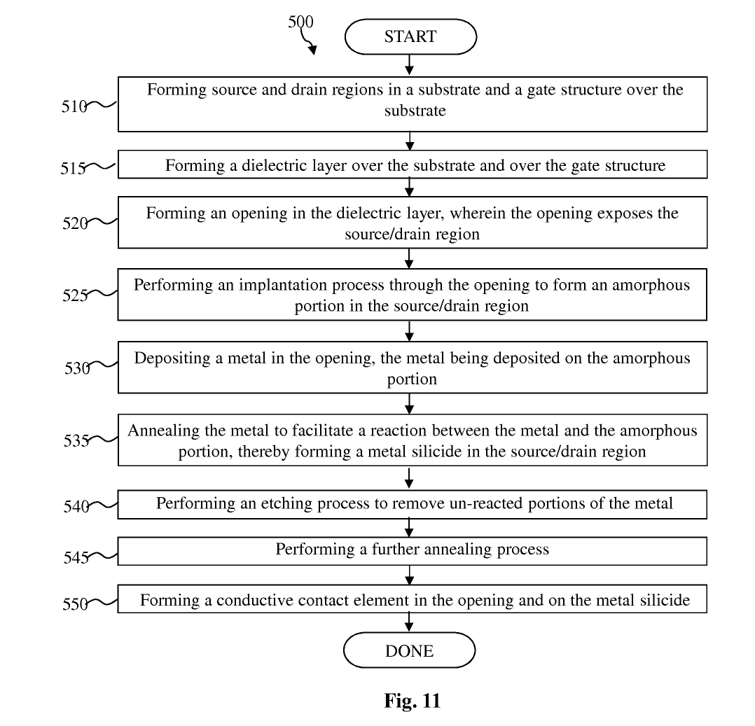

FIG. 11 is a flowchart of a method 500 for fabricating a semiconductor device in accordance with various aspects of the present disclosure. The method 500 includes a step 510 of forming source and drain regions in a substrate and forming a gate structure over a substrate. In some embodiments, the forming of the gate structure may include a gate-replacement process to form a high-k metal gate. For example, a polysilicon dummy gate electrode may be formed over a high-k gate dielectric, and then after the formation of source and drain regions, the dummy polysilicon gate electrode may be replaced by a metal gate.

The method 500 may include a step 515 of forming a dielectric layer over the substrate and over the gate structure. In embodiments where a gate-replacement process was used to form a high-k metal gate, the dielectric layer may be formed after the dummy gate electrode is formed, but before the metal gate electrode is formed, since the metal gate electrode would be formed within an opening in the dielectric layer created by the removal of the dummy gate electrode.

The method 500 may include a step 520 of forming an opening in the dielectric layer. The opening is formed to expose a portion of the source/drain. The method 500 may include a step 525 of performing an implantation process through the opening to form an amorphous portion in the source/drain region. In some embodiments, the implantation process is a cold implantation process, which may be performed at a temperature range from about −60 degrees Celsius to about −100 degrees Celsius.

The method 500 may include a step 530 of depositing a metal in the opening. The metal is deposited on the amorphous portion. In some embodiments, the metal contains nickel.

The method 500 may include a step 535 of annealing the metal to facilitate a reaction between the metal and the amorphous portion. This reaction forms a metal silicide in the source/drain region. In some embodiments, the annealing process performed in step 535 has a spike profile (or is a spike annealing process). For example, the annealing process may have a sharp temperature increase as shown in FIG. 6B. In some embodiments, the annealing process is performed at a temperature in a range from about 200 degrees Celsius to about 300 degrees Celsius.

The method 500 may include a step 540 of performing an etching process to remove un-reacted portions of the metal after the metal silicide is formed. In some embodiments, the etching process is a selective etching process, so that the metal may be etched away while leaving the metal silicide intact.

The method 500 may include a step 545 of performing a further annealing process after the un-reacted portions of the metal are removed. Unlike the annealing process performed in the step 535, the further annealing process in step 545 does not necessarily have a spike-profile.

The method 500 may include a step 550 of forming a conductive contact element in the opening and on the metal silicide after the further annealing process is performed.

It is understood that additional process steps may be performed before, during, or after the steps 510-550 discussed above to complete the fabrication of the semiconductor device. For example, the method 500 may include additional processes to form an interconnect structure over the contact and over the gate structure. The interconnect structure may include a plurality of metal layers that are interconnected by vias. The method 500 may also include additional packaging, testing, and dicing processes, which are not discussed herein for reasons of simplicity.

The embodiments of the present disclosure offer advantages over existing art, though it is understood that other embodiments may offer different advantages, not all advantages are necessarily discussed herein, and that no particular advantage is required for all embodiments. One of the advantages is that, by using an ion implantation process to form the amorphous silicon in the substrate, it creates an effective boundary for the metal silicide, so as to reduce silicide extrusion that would otherwise lead to potential defects. Another advantage is that the amorphous silicon allows the volume of the metal silicides to be greater, thereby reducing contact resistance. Another advantage is that the cold implantation temperatures minimize recrystallization, thereby preserving the volume of the metal silicides and also improving an Iₒₙ−I_{off} performance. Yet one more advantage is that the unique annealing profile of the first annealing process reduces silicide grain conglomeration, thereby leading to more uniform silicide grain growth compared to conventional methods. The more uniform grain growth leads to reduced leakage and better stress voltage tolerance.

Some embodiments of the present disclosure involve a semiconductor device. The semiconductor device includes a transistor having a source/drain region. A conductive contact is disposed over the source/drain region. A silicide element is disposed below the conductive contact. The silicide element has a non-angular cross-sectional profile.

Some embodiments of the present disclosure involve a semiconductor device. The semiconductor device includes a silicon substrate. A gate structure is disposed over the silicon substrate. A source/drain is formed in the silicon substrate and adjacent to the gate structure. A contact is disposed over the source/drain. The contact contains a metal material. A metal silicide forms an interface between the contact and the source/drain. The metal silicide has a non-triangular shape in a cross-sectional side view.

Some embodiments of the present disclosure involve a method of fabricating a semiconductor device. A substrate is provided. The substrate has a source/drain region formed therein and a dielectric layer formed thereover. An opening is formed in the dielectric layer. The opening exposes the source/drain region. An implantation process is performed through the opening to form an amorphous portion in the source/drain region. A metal is deposited in the opening. The metal is deposited on the amorphous portion. The metal is annealed to facilitate a reaction between the metal and the amorphous portion, thereby forming a metal silicide in the source/drain region.

Some embodiments of the present disclosure involve a method of fabricating a semiconductor device. A substrate is provided. The substrate has a source/drain region formed therein and a dielectric layer formed thereover. An opening is formed in the dielectric layer. The opening exposes the source/drain region. A metal is deposited on the substrate in the opening. An annealing process is performed to cause the metal to react with a portion of the substrate disposed therebelow. A reaction of the metal and the portion of the substrate forms a metal silicide in the source/drain region. The annealing process has a spike profile.

Some embodiments of the present disclosure involve a method of fabricating a semiconductor device. A substrate is provided. The substrate has a source/drain region formed therein and a dielectric layer formed thereover. A contact hole is etched in the dielectric layer to expose a portion of the source/drain region. A metal material is formed on the source/drain region exposed by the opening. A first annealing process is performed to facilitate a reaction between the metal material and the portion of the source/drain region disposed therebelow, thereby forming a metal silicide in the substrate, wherein the first annealing process is a spike annealing process. A remaining portion of the metal material is removed after the performing of the first annealing process. Thereafter, a second annealing process is performed. Thereafter, a contact is formed in the contact hole and on the metal silicide.

Some embodiments of the present disclosure involve a method of fabricating a semiconductor device. A substrate is provided. The substrate has a source/drain region formed therein and a dielectric layer formed thereover. An opening is formed in the dielectric layer to expose a portion of the source/drain region. A nickel material is formed on the source/drain region exposed by the opening. A first annealing process is performed to facilitate a reaction between the nickel material and the portion of the source/drain region disposed therebelow, thereby forming a nickel silicide in the substrate. The first annealing process has a sharp ascension in temperature and is performed at an annealing temperature in a range from about 200 degrees Celsius to about 300 degrees Celsius. A remaining portion of the nickel material is removed after the performing of the first annealing process. Thereafter, a second annealing process is performed. Thereafter, a conductive contact is formed in the opening. The conductive contact is formed on the nickel silicide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
providing a substrate having a source/drain region formed therein and a dielectric layer formed thereover;
forming an opening in the dielectric layer, wherein the opening exposes the source/drain region;
depositing a metal on the substrate in the opening; and
performing an annealing process that causes the metal to react with a portion of the substrate disposed therebelow, wherein a reaction of the metal and the portion of the substrate forms a metal silicide in the source/drain region, and wherein the annealing process has a spike profile.

2. The method of claim 1, wherein the annealing process is performed at an annealing temperature in a range from about 200 degrees Celsius to about 300 degrees Celsius.

3. The method of claim 2, wherein the annealing process has an annealing duration that is shorter than about 5 seconds

4. The method of claim 1, further comprising: before the depositing of the metal, performing an implantation process through the opening.

5. The method of claim 4, wherein the implantation process is performed in a manner so as to amorphize the portion of the substrate.

6. The method of claim 1, further comprising: after the annealing process is performed, forming a conductive contact element in the opening and on the metal silicide.

7. The method of claim 6, further comprising: after the annealing process is performed and before the forming of the conductive contact, removing portions of the metal that has not reacted with the portion of the substrate.

8. The method of claim 7, further comprising: after the removing of the portions of the metal and before the forming of the conductive contact, performing a further annealing process, wherein the further annealing process is free of a spike profile.

9. The method of claim 1, further comprising: before the forming of the opening, forming a gate structure over the substrate.

10. The method of claim 9, wherein the forming of the gate structure comprises forming a high-k gate dielectric and forming a metal gate electrode over the high-k gate dielectric.

11. A method of fabricating a semiconductor device, comprising:
providing a substrate having a source/drain region formed therein and a dielectric layer formed thereover;
etching a contact hole in the dielectric layer to expose a portion of the source/drain region;
forming a metal material on the source/drain region exposed by the opening;
performing a first annealing process to facilitate a reaction between the metal material and the portion of the source/drain region disposed therebelow, thereby forming a metal silicide in the substrate, wherein the first annealing process is a spike annealing process;
removing a remaining portion of the metal material after the performing of the first annealing process;
thereafter performing a second annealing process; and
thereafter forming a contact in the contact hole, the contact being formed on the metal silicide.

12. The method of claim 11, wherein the second annealing process is not a spike annealing process.

13. The method of claim 11, wherein the first annealing process is performed at an annealing temperature in a range from about 200 degrees Celsius to about 300 degrees Celsius.

14. The method of claim 13, wherein the first annealing process has an annealing duration shorter than about 5 seconds.

15. The method of claim 11, further comprising: before the forming of the metal material, performing an implantation process through the contact hole to amorphize the portion of the source/drain region.

16. The method of claim 11, further comprising: before the etching of the contact hole, forming a gate structure over the substrate.

17. The method of claim 16, wherein the forming of the gate structure comprises forming a high-k metal gate.

18. A method of fabricating a semiconductor device, comprising:
providing a silicon substrate having a source/drain region formed therein and a dielectric layer formed thereover;
forming an opening in the dielectric layer to expose a portion of the source/drain region;
forming a nickel material on the source/drain region exposed by the opening;
performing a first annealing process to facilitate a reaction between the nickel material and the portion of the source/drain region disposed therebelow, thereby forming a nickel silicide in the substrate, wherein the first annealing process has a sharp ascension in temperature and is performed at an annealing temperature in a range from about 200 degrees Celsius to about 300 degrees Celsius;
removing a remaining portion of the nickel material after the performing of the first annealing process;
thereafter performing a second annealing process; and
thereafter forming a conductive contact in the opening, the conductive contact being formed on the nickel silicide.

19. The method of claim 18, wherein the first annealing process has an annealing duration shorter than about 5 seconds.

20. The method of claim 18, further comprising: before the forming of the nickel material, performing an implantation process through the opening to amorphize the portion of the source/drain region.
